(19) United States
(12) Patent Application Publication
(10) Pub. No.: US 2026/0304689 A1
(43) Pub. Date: Oct. 1, 2026

(54) IMMERSION COOLING DEVICE

(71) Applicant: MITSUBISHI HEAVY INDUSTRIES, LTD., Tokyo (JP)

(72) Inventors: Nobuhide Hara, Tokyo (JP); Sumiu Uchida, Tokyo (JP); Hiroko Kitamoto, Tokyo (JP)

(73) Assignee: MITSUBISHI HEAVY INDUSTRIES, LTD., Tokyo (JP)

(21) Appl. No.: 18/996,467

(22) PCT Filed: Feb. 20, 2023
(86) PCT No.: PCT/JP2023/005908

§ 371 Date: Jan. 17, 2025

(30) Foreign Application Priority Data
Jul. 22, 2022 (JP) 2022-117547

(51) Int. Cl. H05K 7/20

(52) U.S. Cl. CPC H05K 7/20272; H05K 7/20236; H05K 7/20263; H05K 7/20772

(57) ABSTRACT

An immersion cooling device cools a heating element provided on a board and includes a casing group including inclined casings, a supply-side header extending in an up-down direction on a second side in a horizontal direction of the casing group and configured to introduce a first refrigerant into each of the inclined casings, a discharge-side header extending in the up-down direction on a first side in the horizontal direction of the casing group and configured to receive introduction of the first refrigerant from each of the inclined casings, a refrigerant pumping unit configured to pump the first refrigerant from the discharge-side header to the supply-side header, and a heat exchange unit configured to cool the first refrigerant by exchanging heat between a second refrigerant supplied from an outside and the first refrigerant.

### TECHNICAL FIELD

The present disclosure relates to an immersion cooling device.

Priority is claimed on Japanese Patent Application No. 2022-117547, filed Jul. 22, 2022, the content of which is incorporated herein by reference.

### BACKGROUND ART

Patent Document 1 discloses a cooling system that cools an electronic device including a heating element. The cooling system includes a cooling tank containing a refrigerant. The electronic device is immersed in the refrigerant of the cooling tank.

The electronic device is disposed in the cooling tank in a plurality of vertical positions. The refrigerant in the cooling tank circulates such that the refrigerant is cooled outside the cooling tank after cooling the heating element and then supplied to the cooling tank again.

### CITATION LIST

### Patent Document

Patent Document 1: PCT International Publication No. WO2016/075838

### SUMMARY OF INVENTION

### Technical Problem

However, in the cooling system described in Patent Document 1, a plurality of electronic devices are vertically disposed in one cooling tank, which results in a large cooling system. Therefore, an object is to improve the disposition efficiency from the viewpoint of reducing the size of the cooling system. Another object is to improve the cooling efficiency is also an issue from the viewpoint of energy saving and refrigerant saving.

The present disclosure has been made in order to achieve the above-described objects, and an object of the present disclosure is to provide an immersion cooling device that can improve the disposition efficiency and the cooling efficiency.

Solution to Problem In order to achieve the above-described objects, the present disclosure provides an immersion cooling device that cools a heating element provided on a board, the immersion cooling device including: a casing group including inclined casings, each of which has a box shape extending downward toward a first side in a horizontal direction and each of which is configured to accommodate the heating element, and configured by arranging the inclined casings in an up-down direction; a supply-side header extending in the up-down direction on a second side in the horizontal direction of the casing group and configured to introduce a first refrigerant into each of the inclined casings; a discharge-side header extending in the up-down direction on the first side in the horizontal direction of the casing group and configured to receive introduction of the first refrigerant from each of the inclined casings; a refrigerant pumping unit configured to pump the first refrigerant from the discharge-side header to the supply-side header; and a heat exchange unit configured to cool the first refrigerant by exchanging heat between a second refrigerant supplied from an outside and the first refrigerant.

### Advantageous Effects of Invention

According to the immersion cooling device according to the present disclosure, the disposition efficiency and the cooling efficiency can be improved.

### BRIEF DESCRIPTION OF DRAWINGS

FIG. 1 A schematic view showing the schematic configuration of an entire immersion cooling device according to an embodiment of the present disclosure.

FIG. 2 A schematic view showing the schematic configuration of an inner portion of an inclined casing according to the embodiment of the present disclosure.

FIG. 3 An enlarged view showing a configuration in the vicinity of an end portion of the inclined casing closer to a supply-side header according to the embodiment of the present disclosure.

FIG. 4 A schematic view showing the schematic configuration of an inner portion of a server housing according to the embodiment of the present disclosure.

FIG. 5 A schematic view showing a rail provided in the inclined casing according to the embodiment of the present disclosure.

FIG. 6 A schematic view showing a schematic configuration of the inner portion of the server housing according to the embodiment of the present disclosure.

### DESCRIPTION OF EMBODIMENTS

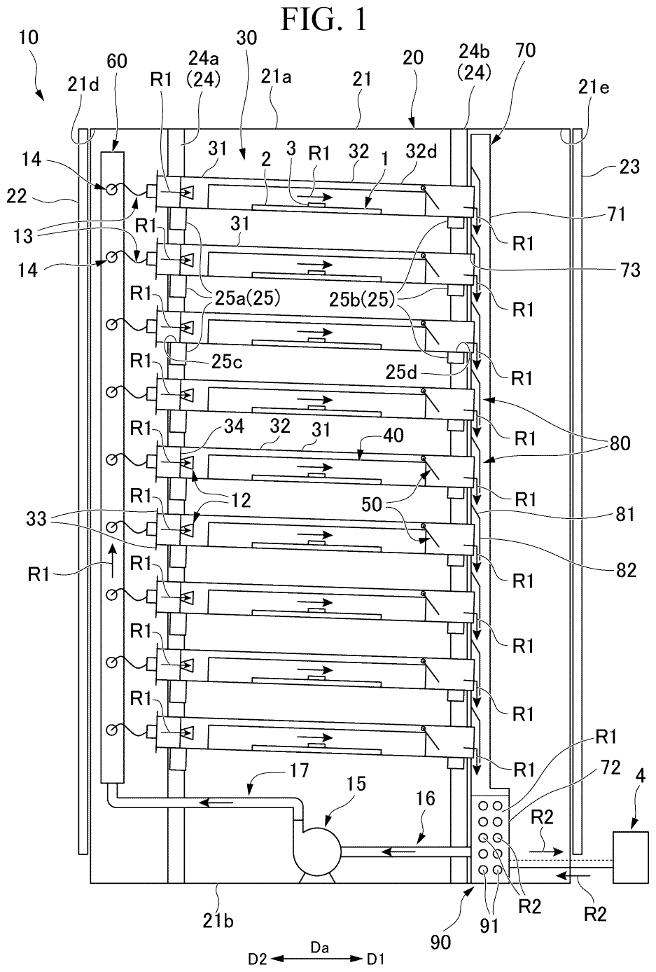

Hereinafter, an immersion cooling device 10 according to an embodiment of the present disclosure will be described with reference to FIGS. 1 to 6.

As shown in FIG. 1, the immersion cooling device 10 is used to cool an electronic device that performs high-speed calculation. In the present embodiment, the immersion cooling device 10 is used for a server 1 installed in a data center. A plurality of servers 1 are provided.

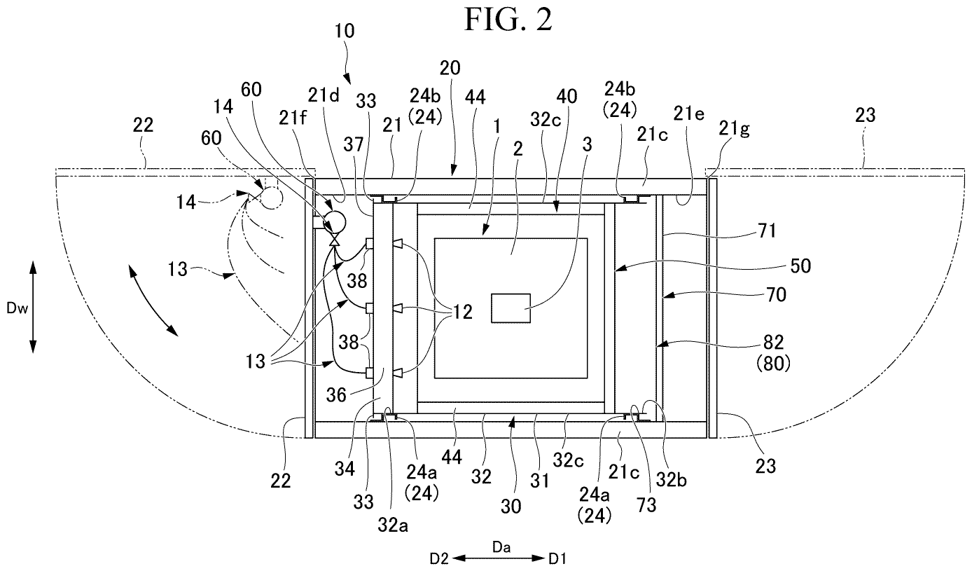

As shown in FIG. 2, the server 1 includes a printed circuit board and an element such as a chip of a CPU or a GPU provided on the printed circuit board. Since the CPU or the GPU is a component responsible for high-speed calculation processing, a high load is applied to the CPU or the GPU, and the CPU or the GPU generates heat at a higher temperature than other portions of the server 1.

A heat exchanger 4 using water as a refrigerant is installed in the data center. Exemplary examples of the heat exchanger 4 include a dry cooler and a chiller. The immersion cooling device 10 according to the present embodiment is provided separately from the heat exchanger 4 and is used to cool an element that generates heat at a high temperature, such as the CPU or the GPU.

Hereinafter, the printed circuit board of the server 1 will be simply referred to as a “board 2”, and the element that generates heat at a particularly high temperature in the board 2, such as the CPU or the GPU, will be referred to as a “heating element 3”.

The board 2 is formed in a rectangular plate shape. The heating element 3 is provided on a surface of the board 2.

### Configuration of Immersion Cooling Device

Subsequently, a configuration of the immersion cooling device 10 will be described.

As shown in FIGS. 1 and 2, the immersion cooling device 10 includes a rack 20, a casing group 30, a seal portion 11, a server housing 40, a nozzle 12, a backflow prevention door 50, a supply-side header 60, a supply-side connection line 13, a valve 14, a discharge-side header 70, a backflow prevention cover 80, a refrigerant pumping unit 15, a first connection pipe 16, a second connection pipe 17, and a heat exchange unit 90.

### Rack

The rack 20 is a cubic storage shelf that accommodates the casing group 30 inside. The rack 20 has a rack body 21, an inlet door 22, an outlet door 23, a support column 24, and a beam 25.

The rack body 21 has an upper wall 21a having a rectangular plate shape extending in a horizontal direction, a lower wall 21b formed in the same shape as the upper wall and located directly below the upper wall, and a pair of side walls 21c that connect side edges of the upper wall 21a and the lower wall 21b to each other and face each other in the horizontal direction. The rack body 21 is formed in a tubular shape that is open on both sides in the horizontal direction orthogonal to a direction in which the pair of side walls 21c face each other.

Hereinafter, an opening direction of the rack body 21 in the horizontal direction will be referred to as a “front-rear direction Da”, and a direction orthogonal to the front-rear direction Da in the horizontal direction will be referred to as a “width direction Dw”. Further, a first side in the front-rear direction Da will be referred to as “a first side D1 in the horizontal direction”, and a second side in the front-rear direction Da will be referred to as “a second side D2 in the horizontal direction”.

Hereinafter, among opening portions of the rack body 21, the opening portion on the second side D2 in the horizontal direction will be referred to as an “inlet-side opening portion 21d”, and the opening portion on the first side D1 in the horizontal direction will be referred to as an “outlet-side opening portion 21e”.

The inlet door 22 is provided in the inlet-side opening portion 21d, and the outlet door 23 is provided in the outlet-side opening portion 21e.

The inlet door 22 is provided on the second side D2 in the horizontal direction of the rack 20. The inlet door 22 is a rectangular plate-shaped member that extends in an up-down direction and that opens and closes a space in the rack 20. The inlet door 22 blocks all portions of the inlet-side opening portion 21d, except for a lower end portion. The inlet door 22 is provided to be rotationally movable, for example, from 80 degrees to 110 degrees about one edge 21f that extends in the up-down direction and that located on the inlet-side opening portion 21d side of an outer surface of the side wall 21c, from a state in which the inlet-side opening portion 21d is blocked. In the present embodiment, the inlet door 22 is rotationally movable by 90 degrees with respect to the edge 21f on the inlet-side opening portion 21d side.

The outlet door 23 is provided on the first side D1 in the horizontal direction of the rack 20. The outlet door 23 is a rectangular plate-shaped member that extends in the up-down direction and that opens and closes a space in the rack 20. The outlet door 23 blocks all portions of the outlet-side opening portion 21e, except for a lower end portion. The outlet door 23 is provided to be rotationally movable, for example, from 80 degrees to 110 degrees about one edge 21g that extends in the up-down direction and that located on the inlet-side opening portion 21d side of the outer surface of the side wall 21c, from a state in which the outlet-side opening portion 21e is blocked. In the present embodiment, the outlet door 23 is rotationally movable by 90 degrees about the edge 21g on the outlet-side opening portion 21e side.

The support column 24 that extends upward from the lower wall 21b of the rack body 21 is provided in a space partitioned by the rack body 21, the inlet door 22, and the outlet door 23.

Four support columns 24 are provided in a quadrangular lattice shape when viewed in the up-down direction. All of the four support columns 24 are fixed to an inner surface of the side wall 21c of the rack body 21. In addition, among the four support columns 24, the two support columns 24 are disposed in the vicinity of the inlet-side opening portion 21d, and the remaining two support columns 24 are disposed in the vicinity of the outlet-side opening portion 21e.

Hereinafter, the two support columns 24 in the vicinity of the inlet-side opening portion 21d will be referred to as “first support columns 24a”, and the two support columns 24 in the vicinity of the outlet-side opening portion 21e will be referred to as “second support columns 24b”.

The two first support columns 24a face each other in the width direction Dw.

Similarly, the two second support columns 24b also face each other in the width direction Dw.

The two first support columns 24a and the two second support columns 24b are connected to each other by the beam 25 extending in the width direction Dw.

The beam 25 is a rod-like member formed in a rectangular cross-sectional shape when viewed in the width direction Dw. Hereinafter, among the beams 25, the beam 25 connecting the two first support columns 24a to each other will be referred to as a “first beam 25a”, and the beam 25 connecting the two second support columns 24b to each other will be referred to as a “second beam 25b”.

A plurality of first beams 25a and a plurality of second beams 25b are provided to be spaced apart from each other at equal intervals in the up-down direction. The first beams 25a and the second beams 25b are provided in the same number, and are provided at the same position in the up-down direction. It should be noted that the first beam 25a is formed to be thicker than the second beam 25b in the up-down direction. In addition, in the first beam 25a and the second beam 25b provided at the same position in the up-down direction, an upper surface 25c of the first beam 25a is located above an upper surface 25d of the second beam 25b.

### Casing Group

The casing group 30 is accommodated in the rack 20 described above. The casing group 30 is an aggregate including inclined casings 31, each of which has a box shape extending in the horizontal direction, and configured by arranging the inclined casings 31 in the up-down direction.

### Inclined Casing

The inclined casing 31 accommodates the board 2 of the server 1. That is, the inclined casing 31 can accommodate the heating element 3 provided on the board 2.

The inclined casing 31 is disposed above the first beam 25a and the second beam 25b which are provided at the same position in the up-down direction, to bridge the first beam 25a and the second beam 25b. As described above, in the first beam 25a and the second beam 25b provided at the same position in the up-down direction, the upper surface 25c of the first beam 25a is located above the upper surface 25d of the second beam 25b, so that the inclined casing 31 is inclined to extend downward toward the first side D1 in the horizontal direction.

A first refrigerant R1 can be stored in the inclined casing 31. The first refrigerant R1 is a refrigerant having insulating properties. The first refrigerant R1 cools the heating element 3 in a liquid-phase state. Exemplary examples of the first refrigerant R1 include a fluorocarbon-based liquid.

Subsequently, the shape of the inclined casing 31 will be described in more detail.

The inclined casing 31 has a casing body 32, a flange 33, a supply-side manifold 34, and a rail 35.

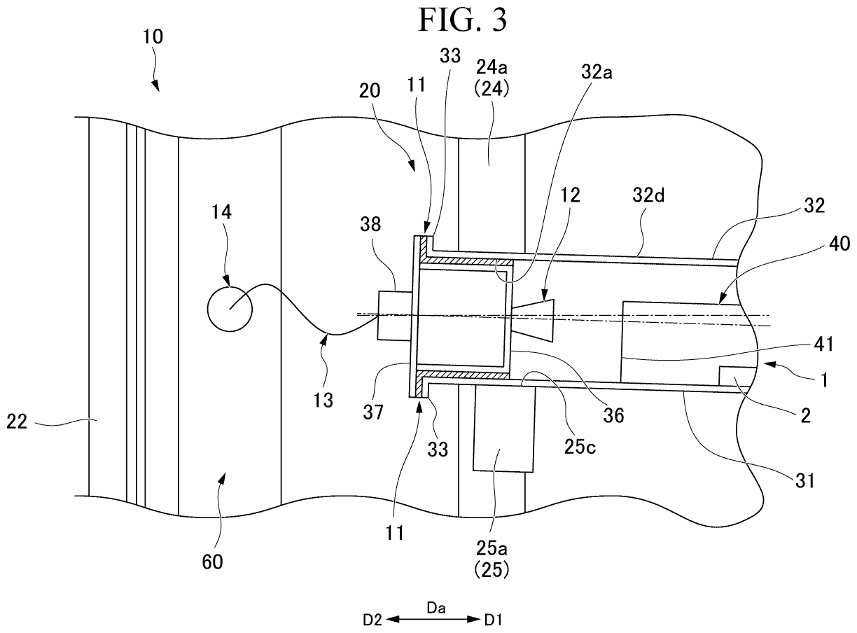

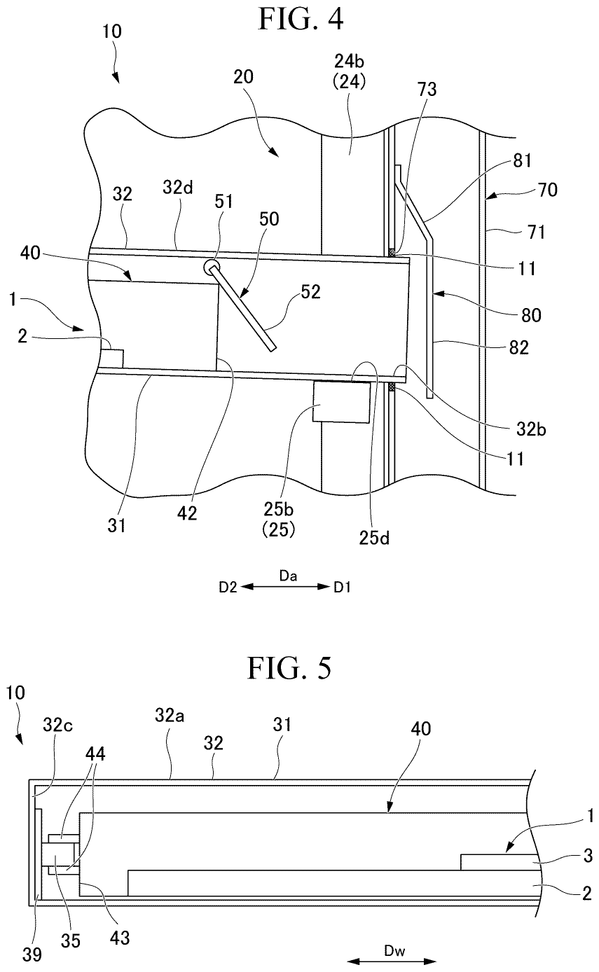

The casing body 32 is a member that constitutes a main part of the inclined casing 31 for accommodating the board 2, and is formed to have a box shape in an outer rectangular plate shape extending in the horizontal direction. The casing body 32 is open in the front-rear direction Da (see FIGS. 3 and 4).

Hereinafter, among opening portions of the casing body 32, the opening portion on the second side D2 in the horizontal direction will be referred to as a “first opening portion 32a”, and the opening portion on the first side D1 in the horizontal direction will be referred to as a “second opening portion 32b”.

As shown in FIGS. 2 and 3, the flange 33 is provided over the entire periphery at an end portion of the casing body 32 on the first opening portion 32a side. The flange 33 is provided to protrude vertically from an outer surface of the casing body 32.

The supply-side manifold 34 is provided in the end portion of the casing body 32 on the first opening portion 32a side. The supply-side manifold 34 extends in the width direction Dw. The supply-side manifold 34 uniformly distributes the first refrigerant R1 introduced from the supply-side header 60, which will be described later, in the casing body 32 in the width direction Dw.

The supply-side manifold 34 has a manifold body 36, a lid portion 37, and an introduction portion 38.

The manifold body 36 is a box-shaped container that extends in the width direction Dw. The manifold body 36 is fitted into the first opening portion 32a. The manifold body 36 is formed in a rectangular cross-sectional shape when viewed in the width direction Dw and is open toward the second side D2 in the horizontal direction.

The lid portion 37 blocks the opening of the manifold body 36 from the second side D2 in the horizontal direction. The lid portion 37 is formed in a rectangular plate shape extending in the width direction Dw. An outer peripheral edge of the lid portion 37 overlaps with the flange 33. The lid portion 37 is fixed to the flange 33 by, for example, bolt fastening.

The introduction portion 38 is provided in an end portion on a side opposite to 11 the manifold body 36 with the lid portion 37 interposed therebetween in the front-rear direction Da. The introduction portion 38 is a tubular member that introduces the first refrigerant R1 from the supply-side header 60 to the supply-side manifold 34. The introduction portion 38 communicates with the manifold body 36. A plurality of (in the present embodiment, three) introduction portions 38 are provided at equal intervals in the width direction Dw.

As shown in FIGS. 2 and 5, the rail 35 is provided in each of the pair of side walls 32c facing each other in the width direction Dw of the casing body 32. The rail 35 protrudes inward in the width direction Dw from a plate material 39 fixed to an inner surface of the side wall 32c, and extends in the front-rear direction Da. The rail 35 is a square bar member formed in a rectangular cross-sectional shape when viewed in the front-rear direction Da.

### Seal Portion

As shown in FIGS. 3 and 4, the seal portion 11 is provided in end portions of each of the inclined casings 31 on the first side D1 in the horizontal direction and on the second side D2 in the horizontal direction. The seal portion 11 suppresses leakage of the first refrigerant R1. More specifically, in the end portion of the inclined casing 31 on the supply-side manifold 34 side, the seal portion 11 is provided between the manifold body 36 and the first opening portion 32a of the inclined casing 31 and between the lid portion 37 and the flange 33 of the inclined casing 31. In addition, in the end portion of the inclined casing 31 on a side opposite to the supply-side manifold 34, the seal portion 11 is provided between an outer surface of the inclined casing 31 and an inflow port 73 of the discharge-side header 70, which will be described later.

### Server Housing

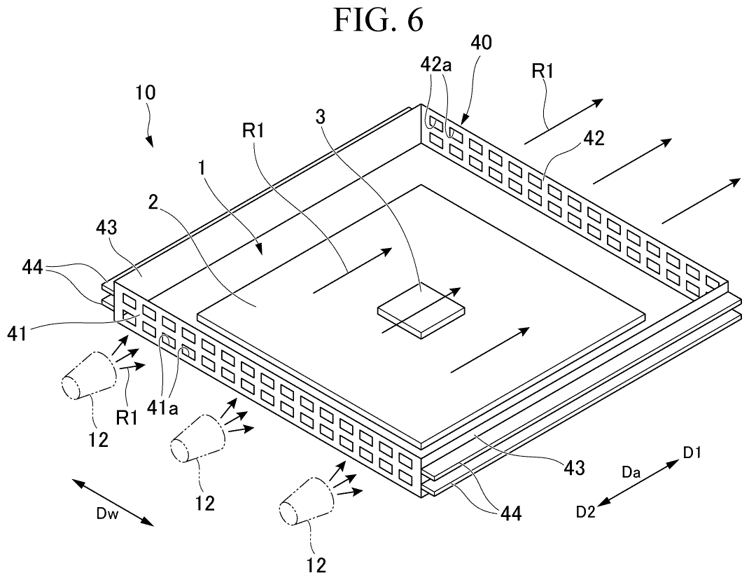

The server housing 40 is provided in the each of the inclined casings 31. The server housing 40 has a box shape in which the board 2 of the server 1 is accommodated. As shown in FIG. 6, the server housing 40 is formed in an outer rectangular plate shape extending in the horizontal direction.

An introduction hole 41a for introducing the first refrigerant R1 into the server housing 40 is formed in a front wall 41 of the server housing 40 on the second side D2 in the horizontal direction. A plurality of introduction holes 41a are formed throughout the front wall 41. In addition, a discharge hole 42a for discharging the first refrigerant R1 in the server housing 40 to the outside is formed in a rear wall 42 of the server housing 40 on the first side D1 in the horizontal direction. A plurality of discharge holes 42a are formed throughout the rear wall 42.

A guide 44 is provided on the pair of side walls 43 facing each other in the width direction Dw of the server housing 40. The guide 44 is a member that positions the server housing 40 and guides the movement of the server housing 40 in the front-rear direction Da in a case where the server housing 40 is taken in and out from the inclined casing 31. The guide 44 protrudes outward in the width direction Dw from the outer surface of the side wall 43, and extends in the front-rear direction Da. The guide 44 is a square bar member formed in a rectangular cross-sectional shape when viewed in the front-rear direction Da. The guide 44 is provided in two pieces on each side wall to be spaced apart from each other in the up-down direction and to interpose the rail 35 of the inclined casing 31 in the up-down direction. Therefore, in a case where the server housing 40 is taken in and out from the inclined casing 31, the server housing 40 moves linearly in the front-rear direction Da along the rail 35.

### Nozzle

As shown in FIGS. 1 and 2, the nozzle 12 is provided in each of the inclined casings 31 and is attached to a bottom outer surface of the supply-side manifold 34 on a side opposite to the lid portion 37. The nozzle 12 communicates with the supply-side manifold 34, and radially jets the first refrigerant R1 supplied from the supply-side header 60 toward the server housing 40. The nozzle 12 is formed in a tapered shape of which a diameter increases toward the first side D1 in the horizontal direction.

### Backflow Prevention Door

The backflow prevention door 50 is provided in each of the inclined casings 31 and prevents the first refrigerant R1 in the inclined casing 31 from flowing back toward the second side D2 in the horizontal direction. The backflow prevention door 50 has a hinge 51 and a backflow prevention door body 52. As shown in FIG. 4, the hinge 51 is disposed in the inclined casing 31, and is attached to an upper wall 32d. The hinge 51 is a hinge with a spring. The backflow prevention door body 52 extends downward from the hinge 51, and extends in the width direction Dw. The backflow prevention door body 52 is maintained in a posture perpendicular to a horizontal plane by an elastic force applied from the spring of the hinge 51.

The backflow prevention door 50 blocks a flow channel of the first refrigerant R1, and opens the flow channel of the first refrigerant R1 in a case where an external force equal to or greater than a predetermined magnitude is applied in a direction of the first side D1 in the horizontal direction. In the present embodiment, in a case where the server housing 40 is not disposed in the inclined casing 31, the backflow prevention door body 52 in the inclined casing 31 is maintained in a posture perpendicular to the horizontal plane by the elastic force of the hinge 51. Therefore, the flow channel of the first refrigerant R1 in the inclined casing 31 is blocked by the backflow prevention door body 52. On the other hand, in a case where the server housing 40 is disposed in the inclined casing 31, the backflow prevention door body 52 is pushed by the server housing 40 and receives the external force in the direction of the first side D1 in the horizontal direction. This external force causes the backflow prevention door body 52 to rotationally move about the hinge 51 and open the flow channel of the first refrigerant R1.

### Supply-Side Header

As shown in FIGS. 1 and 2, the supply-side header 60 is provided on an inner surface of the inlet door 22. The supply-side header 60 extends in the up-down direction on the second side D2 in the horizontal direction of the casing group 30, and can introduce the first refrigerant R1 into each of the inclined casings 31. The supply-side header 60 is formed in a cylindrical shape extending in the up-down direction. The supply-side header 60 is provided with a plurality of supply-side connection lines 13.

### Supply-Side Connection Line)

The supply-side connection line 13 connects the supply-side header 60 and each of the inclined casings 31 to each other in a state in which the supply-side header 60 and each of the inclined casings 31 communicate with each other. A plurality of (in the present embodiment, three) supply-side connection lines 13 are provided for each of the inclined casings 31, and are connected to the introduction portion 38 of the corresponding inclined casing 31. The valve 14 that can open and close the supply-side connection line 13 is provided in the supply-side connection line 13.

### Valve

The valve 14 is provided for each of the inclined casings 31. In the present embodiment, at the bases of three supply-side connection lines 13 connected to the corresponding inclined casing 31 by one valve 14, the three supply-side connection lines 13 can be opened and closed at the same time. The supply-side connection line 13 is a flexible tube, and is deformable in accordance with the rotational movement of the inlet door 22.

### Discharge-Side Header

The discharge-side header 70 is accommodated in the rack body 21, and extends in the up-down direction on the first side D1 in the horizontal direction of the casing group 30. The first refrigerant R1 is introduced from each of the inclined casings 31 into the discharge-side header 70. The discharge-side header 70 has a discharge-side header body 71 and a storage portion 72.

The discharge-side header body 71 is adjacent to the first side D1 in the horizontal direction of the casing group 30. The discharge-side header body 71 is a box-shaped container having an outer rectangular plate shape extending in the up-down direction. In the present embodiment, both end portions of the discharge-side header body 71 in the width direction Dw are fixed to the inner surface of the side wall 21c of the rack body 21. In the discharge-side header body 71, the inflow port 73 is provided at each position corresponding to each of the inclined casings 31. The first refrigerant R1 introduced from the inclined casing 31 flows in the inflow port 73. In the present embodiment, the second opening portion 32b of the corresponding inclined casing 31 is inserted into each inflow port 73. In addition, the seal portion 11 described above is provided between the inflow port 73 and the inclined casing 31.

The storage portion 72 is provided in a lower end portion of the inclined casing 31. The storage portion 72 stores the refrigerant introduced into the discharge-side header body 71. A dimension of the storage portion 72 in the front-rear direction Da is larger than a dimension of the inclined casing 31 in the front-rear direction Da. The storage portion 72 is disposed on the lower wall 21b of the rack body 21.

### Backflow Prevention Cover

The backflow prevention cover 80 is provided at a position corresponding to each inflow port 73 in the discharge-side header 70. The backflow prevention cover 80 prevents the first refrigerant R1 from flowing back into the inclined casing 31 from the discharge-side header 70. The backflow prevention cover 80 extends in the width direction Dw and covers the inflow port 73 with a gap from above and from the first side D1 in the horizontal direction. As shown in FIG. 4, the backflow prevention cover 80 has an upper wall 81 and a rear wall 82.

The upper wall 81 is provided on an inner surface of the discharge-side header 70 on a side on which the inflow port 73 is formed. The upper wall 81 is attached above the corresponding inflow port 73, for example, by welding or the like, and extends in the front-rear direction Da. The upper wall 81 is linearly inclined to be gradually located downward toward the rear side.

The rear wall 82 is provided in a rear end of the upper wall 81, and extends vertically downward from the rear end of the upper wall 81. The rear wall 82 is formed at a position spaced rearward from the second opening portion 32b of the inclined casing 31, to cover the entire second opening portion 32b. The rear wall 82 is integrally formed with the upper wall 81.

### Refrigerant Pumping Unit

As shown in FIG. 1, the refrigerant pumping unit 15 is accommodated in the rack 20, and is disposed below the casing group 30. The refrigerant pumping unit 15 is connected to a lower portion of the discharge-side header 70 by the first connection pipe 16, and is connected to a lower portion of the supply-side header 60 by the second connection pipe 17. The first connection pipe 16 allows the discharge-side header 70 and the refrigerant pumping unit 15 to communicate with each other, and the second connection pipe 17 allows the supply-side header 60 and the refrigerant pumping unit 15 to communicate with each other. The refrigerant pumping unit 15 pumps the first refrigerant R1 from the lower portion of the discharge-side header 70 to the lower portion of the supply-side header 60. The refrigerant pumping unit 15 according to the present embodiment is a pump.

### Heat Exchange Unit

The heat exchange unit 90 is provided below the casing group 30. In the present embodiment, the heat exchange unit 90 is provided in the storage portion 72 of the discharge-side header 70. The heat exchange unit 90 cools the first refrigerant R1 by exchanging heat between a second refrigerant R2 supplied from the outside and the first refrigerant R1.

The heat exchange unit 90 according to the present embodiment is a plurality of heat transfer pipes 91 that penetrate the storage portion 72 in the width direction Dw.

The heat transfer pipe 91 communicates with the heat exchanger 4 provided outside.

The second refrigerant R2 of the heat exchanger 4 flows inside the heat transfer pipe 91. The plurality of heat transfer pipes 91 extend parallel to each other and are disposed at equal intervals.

In the present embodiment, the second refrigerant R2 in the heat transfer pipe 91 flows in a counter flow direction opposite to a flow direction of the first refrigerant R1 in at least a partial region in the storage portion 72.

### Circulation of First Refrigerant

Subsequently, the circulation of the first refrigerant R1 in the immersion cooling device 10 will be described.

First, in a case where the refrigerant pumping unit 15 is operated, the first refrigerant R1 is supplied from the supply-side header 60 to each of the inclined casings 31. In this case, the first refrigerant R1 is jetted into the inclined casing 31 by a plurality of nozzles 12. The first refrigerant R1 flows in each of the inclined casings 31 in the front-rear direction Da, as a jet stream. The first refrigerant R1 in the inclined casing 31 flows in the server housing 40, passes through the heating element 3, and exchanges heat with the heating element 3. As a result, the heating element 3 is cooled. On the other hand, the first refrigerant R1 is heated by receiving heat of the heating element 3. Then, the first refrigerant R1 is discharged from the server housing 40 and is introduced from each of the inclined casings 31 into the discharge-side header 70. The first refrigerant R1 flows from the upper side to the lower side in the discharge-side header 70 due to the pressure of the refrigerant pumping unit 15 and the dead weight.

Then, the first refrigerant R1 is temporarily stored in the storage portion 72 of the discharge-side header 70.

Meanwhile, in the heat transfer pipe 91, the second refrigerant R2 flows in the width direction Dw.

The first refrigerant R1 exchanges heat with the second refrigerant R2 in a process of flowing inside the discharge-side header 70. As a result, the first refrigerant R1 is cooled, and the second refrigerant R2 is heated. The second refrigerant R2 is sent to the heat exchanger 4 provided outside, after exchanging heat with the first refrigerant R1. The second refrigerant R2 is cooled by the heat exchanger 4, and is supplied to each heat transfer pipe 91 again.

In a case where the first refrigerant R1 is cooled by exchanging heat with the second refrigerant R2, the first refrigerant R1 is pumped again to the supply-side header 60 by the refrigerant pumping unit 15. Then, the first refrigerant R1 is supplied to the inclined casing 31 again as described above. In this manner, the first refrigerant R1 circulates in the immersion cooling device 10.

### Operations and Effects

With the immersion cooling device 10 according to the present embodiment, the following operations and effects are exhibited.

In the present embodiment, the immersion cooling device 10 includes the casing group 30 configured by arranging the inclined casings 31, each of which can accommodate the heating element 3, in the up-down direction, the supply-side header 60 that extends in the up-down direction on the second side D2 in the horizontal direction of the casing group 30 and that can introduce the first refrigerant R1 into each of the inclined casings 31, and the discharge-side header 70 that extends in the up-down direction on the first side D1 in the horizontal direction of the casing group 30 and that receives introduction of the first refrigerant R1 from each of the inclined casings 31.

The inclined casing 31 extends downward toward the first side D1 in the horizontal direction.

The casing group 30 is configured by arranging the plurality of inclined casings 31 in the up-down direction. As a result, it is possible to present the plurality of inclined casings 31 from being randomly disposed and spreading in the horizontal direction, and it is possible to improve the disposition efficiency.

In addition, since each of the inclined casings 31 extends downward toward the first side D1 in the horizontal direction, the first refrigerant R1 can smoothly flow in the inclined casing 31 in the horizontal direction. As a result, the immersion cooling device 10 can quickly guide the first refrigerant R1, which has absorbed heat from the heating element 3, to the discharge-side header 70, and thus the cooling efficiency can be improved.

In the present embodiment, the immersion cooling device 10 further includes the plurality of supply-side connection lines 13 that connect the supply-side header 60 and each of the inclined casings 31 to each other in a state in which the supply-side header 60 and each of the inclined casings 31 communicate with each other, and the valve 14 that is provided for each of the inclined casings 31 and that can open and close the supply-side connection lines 13.

As a result, it is possible to easily stop the supply of the first refrigerant R1 to the inclined casing 31 connected to the supply-side connection line 13, by operating the valve 14 to block the supply-side connection line 13. Therefore, it is possible to easily take out any inclined casing 31. Therefore, it is easy to take out and perform the maintenance for each of the inclined casings 31.

In the present embodiment, the immersion cooling device 10 further includes the backflow prevention door 50 that is provided in each of the inclined casings 31, that blocks the flow channel of the first refrigerant R1, and that opens the flow channel of the first refrigerant R1 in a case where the external force equal to or greater than the predetermined magnitude is applied in the direction of the first side D1 in the horizontal direction.

As a result, in the inclined casing 31, it is possible to prevent the first refrigerant R1 from flowing back to the second side D2 in the horizontal direction without hindering the first refrigerant R1 from flowing to the first side D1 in the horizontal direction.

In the present embodiment, the discharge-side header 70 is provided with the inflow port 73 through which the first refrigerant R1 introduced from the inclined casing 31 flows in, at the position corresponding to each of the inclined casings 31. The immersion cooling device 10 further includes the backflow prevention cover 80 that is provided at the position corresponding to each inflow port 73 in the discharge-side header 70 and that covers the inflow port 73 from above and from the first side D1 in the horizontal direction with a gap.

As a result, it is possible to prevent the first refrigerant R1 from flowing back into the inclined casing 31 in a process in which the first refrigerant R1 flows downward in the discharge-side header 70, without hindering the first refrigerant R1 from being discharged from the inclined casing 31 toward the discharge-side header 70.

As described above, since the first refrigerant R1 is prevented from flowing back by providing the backflow prevention door 50 or the backflow prevention cover 80 in the immersion cooling device 10, the first refrigerant R1 flows more smoothly in the inclined casing 31. Therefore, the immersion cooling device 10 can more quickly guide the first refrigerant R1, which has absorbed heat from the heating element 3, to the discharge-side header 70, and thus the cooling efficiency can be further improved.

As in the present embodiment, by providing the valve 14, the backflow prevention door 50, and the backflow prevention cover 80 in the immersion cooling device 10, it is possible to stop the flow of the first refrigerant R1 in each of the inclined casings 31 without stopping the entire flow of the first refrigerant R1 in the immersion cooling device 10. As a result, it is possible to individually take out the server 1 accommodated in the inclined casing 31, and to individually maintain the server 1.

In the present embodiment, the immersion cooling device 10 further includes the rack 20 that accommodates the casing group 30. The rack 20 has the inlet door 22 that can open and close a space in the rack 20 on the second side D2 in the horizontal direction. The supply-side header 60 is provided in the inlet door 22.

When the inlet door 22 is opened, the supply-side header 60 also moves along with the inlet door 22. Therefore, it is easy to take out the inclined casing 31. As a result, it is easier to take out the server 1 and perform the maintenance for each of the inclined casings 31.

In the present embodiment, the heat exchange unit 90 is provided below the casing group 30.

As a result, it is possible to cool the first refrigerant R1 by the heat exchanger 4 without filling the supply-side header 60 and the discharge-side header 70 with the first refrigerant R1, and thus it is possible to reduce an amount of the first refrigerant R1 used.

In the present embodiment, the immersion cooling device 10 further includes the nozzle 12 that is provided in each of the inclined casings 31 and that jets the first refrigerant R1 supplied from the supply-side header 60.

As a result, the immersion cooling device 10 can generate convection in the first refrigerant R1 in the inclined casing 31 by the jetting of the nozzle 12 while smoothly flowing the first refrigerant R1 in the inclined casing 31 by the inclination of the inclined casing 31. Therefore, the efficiency of heat exchange between the heating element 3 and the first refrigerant R1 is improved, and thus the cooling efficiency can be further improved.

In the present embodiment, the immersion cooling device 10 further includes the seal portions 11 that are provided in the end portions of each of the inclined casings 31 on the first side D1 in the horizontal direction and on the second side D2 in the horizontal direction, and that suppress leakage of the first refrigerant R1.

As a result, the leakage of the first refrigerant R1 is suppressed when the first refrigerant R1 is introduced into the inclined casing 31 and the first refrigerant R1 is discharged from the inclined casing 31, and thus the amount of the first refrigerant R1 used can be reduced.

### Other Embodiments

Although the embodiment of the present disclosure has been described in detail above with reference to the drawings, the specific configuration is not limited to this embodiment, and design changes and the like that do not depart from the gist of the present disclosure are also included.

In the above-described embodiment, the heat exchange unit 90 is provided in the storage portion 72 of the discharge-side header 70, but the present disclosure is not limited to this. The heat exchange unit 90 may be provided directly below the casing group 30 and may exchange heat between the first refrigerant R1 and the second refrigerant R2 in the first connection pipe 16 and the second connection pipe 17 that connect the supply-side header 60 and the discharge-side header 70 to each other.

In addition, in the above-described embodiment, the heat exchange unit 90 is the plurality of heat transfer pipes 91 that penetrate the storage portion 72 in the width direction Dw, but the present disclosure is not limited to this. The heat exchange unit 90 may be, for example, the heat transfer pipe 91 extending in the up-down direction in the discharge-side header 70. In this case, the backflow prevention door 50 and the backflow prevention cover 80 need not be provided. In a case where the backflow prevention door 50 and the backflow prevention cover 80 are not provided, the first refrigerant R1 is directly blown from the inclined casing 31 to the heat transfer pipe 91, so that the efficiency of heat exchange between the first refrigerant R1 and the second refrigerant R2 may be improved.

In addition, in the above-described embodiment, the second refrigerant R2 in the heat transfer pipe 91 flows in the counter flow direction opposite to the flow direction of the first refrigerant R1 in at least a partial region in the storage portion 72, but the present disclosure is not limited to this. The second refrigerant R2 in the heat transfer pipe 91 may flow in the same direction as the first refrigerant R1 in the storage portion 72, and the flow of the second refrigerant R2 in the heat transfer pipe 91 may be set without considering the flow of the first refrigerant R1.

### <Supplementary Note>

The immersion cooling device 10 described in each embodiment is understood, for example, as follows.

(1) A first aspect relates to an immersion cooling device 10 that cools a heating element 3 provided on a board 2, the immersion cooling device 10 including: a casing group 30 including inclined casings 31, each of which has a box shape extending downward toward a first side D1 in a horizontal direction and each of which is configured to accommodate the heating element 3, and configured by arranging the inclined casings 31 in an up-down direction; a supply-side header 60 extending in the up-down direction on a second side D2 in the horizontal direction of the casing group 30 and configured to introduce a first refrigerant R1 into each of the inclined casings 31; a discharge-side header 70 extending in the up-down direction on the first side D1 in the horizontal direction of the casing group 30 and configured to receive introduction of the first refrigerant R1 from each of the inclined casings 31; a refrigerant pumping unit 15 configured to pump the first refrigerant R1 from the discharge-side header 70 to the supply-side header 60; and a heat exchange unit 90 configured to cool the first refrigerant R1 by exchanging heat between a second refrigerant R2 supplied from an outside and the first refrigerant R1.

The casing group 30 is configured by arranging the plurality of inclined casings 31 in the up-down direction. In addition, since each of the inclined casings 31 extends downward toward the first side D1 in the horizontal direction, the first refrigerant R1 can smoothly flow in the inclined casing 31 in the horizontal direction.

(2) A second aspect relates to the immersion cooling device 10 according to (1), which may further include: a plurality of supply-side connection lines 13 configured to connect the supply-side header 60 and each of the inclined casings 31 to each other in a state in which the supply-side header 60 and each of the inclined casings 31 communicate with each other; and a valve 14 provided for each of the inclined casings 31 and configured to open and close the supply-side connection lines 13.

As a result, it is possible to easily stop the supply of the first refrigerant R1 to the inclined casing 31 connected to the supply-side connection line 13, by operating the valve 14 to block the supply-side connection line 13. Therefore, it is possible to easily take out any inclined casing 31.

(3) A third aspect relates to the immersion cooling device 10 according to (1) or (2), which may further include: a backflow prevention door 50 provided in each of the inclined casings 31, configured to block a flow channel of the first refrigerant R1, and configured to open the flow channel of the first refrigerant R1 in a case where an external force equal to or greater than a predetermined magnitude is applied in a direction of the first side D1 in the horizontal direction.

As a result, in the inclined casing 31, it is possible to prevent the first refrigerant R1 from flowing back to the second side D2 in the horizontal direction without hindering the first refrigerant R1 from flowing to the first side D1 in the horizontal direction.

(4) A fourth aspect relates to the immersion cooling device 10 according to any one of (1) to (3), in which the discharge-side header 70 may be provided with an inflow port 73 through which the first refrigerant R1 introduced from the inclined casings 31 flows in, at a position corresponding to each of the inclined casings 31, and the immersion cooling device 10 may further include a backflow prevention cover 80 provided at a position corresponding to each inflow port 73 in the discharge-side header 70 and configured to cover the inflow port 73 with a gap from above and from the first side D1 in the horizontal direction.

As a result, it is possible to prevent the first refrigerant R1 from flowing back into the inclined casing 31 in a process in which the first refrigerant R1 flows downward in the discharge-side header 70, without hindering the first refrigerant R1 from being discharged from the inclined casing 31 toward the discharge-side header 70.

(5) A fifth aspect relates to the immersion cooling device 10 according to any one of (1) to (4), which may further include: a rack 20 configured to accommodate the casing group 30, in which the rack 20 has an inlet door 22 configured to open and close a space in the rack 20, on the second side D2 in the horizontal direction, and the supply-side header 60 is provided on the inlet door 22.

When the inlet door 22 is opened, the supply-side header 60 also moves along with the inlet door 22. Therefore, it is easy to take out the inclined casing 31.

(6) A sixth aspect relates to the immersion cooling device 10 according to any one of (1) to (5), in which the heat exchange unit 90 may be provided below the casing group 30.

As a result, it is possible to cool the first refrigerant R1 by the heat exchanger 4 without filling the supply-side header 60 and the discharge-side header 70 with the first refrigerant R1.

(7) A seventh aspect relates to the immersion cooling device 10 according to any one of (1) to (6), which may further include: a nozzle 12 provided in each of the inclined casings 31 and configured to jet the first refrigerant R1 supplied from the supply-side header 60.

As a result, the immersion cooling device 10 can generate convection in the first refrigerant R1 in the inclined casing 31 by the jetting of the nozzle 12 while smoothly flowing the first refrigerant R1 in the inclined casing 31 by the inclination of the inclined casing 31.

(8) An eighth aspect relates to the immersion cooling device 10 according to any one of (1) to (7), which may further include: seal portions 11 provided in end portions of each of the inclined casings 31 on the first side D1 in the horizontal direction and on the second side D2 in the horizontal direction and configured to suppress leakage of the first refrigerant R1.

As a result, the leakage of the first refrigerant R1 is suppressed when the first refrigerant R1 is introduced into the inclined casing 31 and the first refrigerant R1 is discharged from the inclined casing 31.

### INDUSTRIAL APPLICABILITY

According to the immersion cooling device according to the present disclosure, the disposition efficiency and the cooling efficiency can be improved.

### REFERENCE SIGNS LIST

1 Server
2 Board
3 Heating element
4 Heat exchanger
10 Immersion cooling device
11 Seal portion
12 Nozzle
13 Supply-side connection line
14 Valve
15 Refrigerant pumping unit
16 First connection pipe
17 Second connection pipe
20 Rack
21 Rack body
21a Upper wall
21b Lower wall
21c Side wall
21d Inlet-side opening portion
21e Outlet-side opening portion
21f Edge
21g Edge
Da Front-rear direction
Dw Width direction
D1 First side in horizontal direction
D2 Second side in horizontal direction
22 Inlet door
23 Outlet door
24 Support column
24a First support column
24b Second support column
25 Beam
31
25a First beam
25b Second beam
25c Upper surface
25d Upper surface
30 Casing group
31 Inclined casing
32 Casing body
32a First opening portion
32b Second opening portion
32c Side wall
32d Upper wall
33 Flange
34 Supply-side manifold
35 Rail
36 Manifold body
37 Lid portion
38 Introduction portion
39 Plate material
40 Server housing
41 Front wall
41a Introduction hole
42 Rear wall
42a Discharge hole
43 Side wall
44 Guide
50 Backflow prevention door
51 Hinge
52 Backflow prevention door body
60 Supply-side header
70 Discharge-side header
71 Discharge-side header body
72 Storage portion
73 Inflow port
80 Backflow prevention cover
81 Upper wall
82 Rear wall
90 Heat exchange unit
91 Heat transfer pipe
R1 First refrigerant
R2 Second refrigerant
A Inclination angle
Da Front-rear direction
D1 First side in horizontal direction
D2 Second side in horizontal direction
Dw Width direction

1. An immersion cooling device that cools a heating element provided on a board, the immersion cooling device comprising:
a casing group including inclined casings, each of which has a box shape extending downward toward a first side in a horizontal direction and each of which is configured to accommodate the heating element, and configured by arranging the inclined casings in an up-down direction;
a supply-side header extending in the up-down direction on a second side in the horizontal direction of the casing group and configured to introduce a first refrigerant into each of the inclined casings;
a discharge-side header extending in the up-down direction on the first side in the horizontal direction of the casing group and configured to receive introduction of the first refrigerant from each of the inclined casings;
a refrigerant pumping unit configured to pump the first refrigerant from the discharge-side header to the supply-side header; and
a heat exchange unit configured to cool the first refrigerant by exchanging heat between a second refrigerant supplied from an outside and the first refrigerant.

2. The immersion cooling device according to claim 1, further comprising:
a plurality of supply-side connection lines configured to connect the supply-side header and each of the inclined casings to each other in a state in which the supply-side header and each of the inclined casings communicate with each other; and
a valve provided for each of the inclined casings and configured to open and close the supply-side connection lines.

3. The immersion cooling device according to claim 1, further comprising:
a backflow prevention door provided in each of the inclined casings, configured to block a flow channel of the first refrigerant, and configured to open the flow channel of the first refrigerant in a case where an external force equal to or greater than a predetermined magnitude is applied in a direction of the first side in the horizontal direction.

4. The immersion cooling device according to claim 1, wherein the discharge-side header is provided with an inflow port through which the first refrigerant introduced from the inclined casings flows in, at a position corresponding to each of the inclined casings, and
the immersion cooling device further comprises a backflow prevention cover provided at a position corresponding to each inflow port in the discharge-side header and configured to cover the inflow port with a gap from above and from the first side in the horizontal direction.

5. The immersion cooling device according to claim 1, further comprising:
a rack configured to accommodate the casing group, wherein
the rack has an inlet door configured to open and close a space in the rack, on the second side in the horizontal direction, and
the supply-side header is provided on the inlet door.

6. The immersion cooling device according to claim 1, wherein the heat exchange unit is provided below the casing group.

7. The immersion cooling device according to claim 1, further comprising:
a nozzle provided in each of the inclined casings and configured to jet the first refrigerant supplied from the supply-side header.

8. The immersion cooling device according to claim 1, further comprising:
seal portions provided in end portions of each of the inclined casings on the first side in the horizontal direction and on the second side in the horizontal direction and configured to suppress leakage of the first refrigerant.
